(19) United States
(12) Patent Application Publication
(10) Pub. No.: US 2015/0137372 A1
(43) Pub. Date: May 21, 2015

(54) SELF FORMING BARRIER LAYER AND METHOD OF FORMING

(71) Applicant: GLOBALFOUNDRIES Inc., Grand Cayman (KY)

(72) Inventor: Moosung M. CHAE, Englewood Cliffs, NJ (US)

(73) Assignee: GLOBALFOUNDRIES Inc., Grand Cayman (KY)

(21) Appl. No.: 14/080,864

(22) Filed: Nov. 15, 2013

(51) Int. Cl. H01L 21/4763; H01L 21/768

(52) U.S. Cl. CPC H01L 21/47635; H01L 21/76865; H01L 21/7685
USPC 257/751; 438/653

(57) ABSTRACT

Methods for forming a self-forming barrier layer and the resulting devices are disclosed. Embodiments may include forming a metal line above a substrate, forming a reagent layer above the metal line and the substrate, forming a dielectric layer on the reagent layer, and transforming the reagent layer into a self-forming barrier layer.

### TECHNICAL FIELD

The present disclosure relates to etching. The present disclosure is particularly applicable to etching metal lines by a subtractive etch for 20 nanometer (nm) technology nodes and beyond.

### BACKGROUND

Subtractive metal etching integration can be an alternative to conventional damascene interconnection processes. Subtractive etching allows for the control of line and surface roughness, which reduces surface scattering of electrons. Subtractive etching also allows for the minimization of electron scattering at grain boundaries with large crystal grains. However, in subtractive etching methods of metals, such as etching of copper (Cu), a barrier layer is deposited by physical vapor deposition (PVD) or atomic layer deposition (ALD) after patterning of the Cu lines. Subsequently, a reactive ion etch (RIE) is used to remove the barrier layer from on the top of the Cu lines and from above dielectrics between Cu lines. The RIE barrier layer removal process can cause damage at the desired barrier sidewalls of the Cu lines, as well as on the liner on top of the Cu lines, which can expose the dielectric to the Cu, allowing Cu to diffuse into the dielectric.

A need, therefore, exists for eliminating the RIE barrier layer removal process step and the resulting device.

### SUMMARY

An aspect of the present disclosure is a method for subtractive metal etching that eliminates the destructive RIE barrier layer removal process step.

Another aspect of the present disclosure is a semiconductor device with metal lines surrounded by a barrier layer that lack damage caused by a RIE process step.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a metal line above a substrate, forming a reagent layer above the metal line and the substrate, forming a dielectric layer on the reagent layer, and transforming the reagent layer into a self-forming barrier layer.

An aspect of the present disclosure includes reacting the dielectric layer with the reagent layer to transform the reagent layer into the self-forming barrier layer. Another aspect includes forming the reagent layer of manganese (Mn), and forming the dielectric layer of a material comprising silicon (Si) and oxygen (O), wherein the self-forming barrier layer is formed of manganese silicon oxide (MnSiOₓ). Yet another aspect includes curing the dielectric layer at 100° to 600° C. to react the dielectric layer with the reagent layer. A further aspect includes forming a second dielectric layer on the substrate prior to forming the metal line, and forming the reagent layer on the second dielectric layer. An additional aspect includes reacting the second dielectric layer with the reagent layer to transform the reagent layer into the self-forming barrier layer. Yet another aspect includes forming the reagent layer to a thickness of 2 to 500 Å. Still another aspect includes forming the metal line by patterning a conductive metal layer above the substrate by subtractive etching. Another aspect includes the conductive metal layer being formed of Cu.

Another aspect of the present disclosure is a device including: a substrate, a metal line above the substrate, and a self-forming barrier layer over the substrate and the metal line.

Aspects include a dielectric layer above the self-forming barrier layer. Another aspect includes the dielectric layer formed of a material comprising Si and O, and the self-forming barrier layer being formed of MnSiOₓ. Still another aspect includes the dielectric layer being cured at 100° to 600° C. to form the self-forming barrier layer. Yet another aspect includes a second dielectric layer below the metal line and above the substrate. Still another aspect includes a hardmask between a top of the metal line and the self-forming barrier layer. A further aspect includes the self-forming barrier layer being formed to a thickness of 2 to 500 Å. Yet another aspect includes the metal line being formed of Cu.)

Another aspect of the present disclosure is a method including forming a first dielectric layer above a substrate, forming a metal layer above the first dielectric layer, patterning the metal layer by subtractive etching to form metal lines, conformally forming a reagent layer above the metal lines on the first dielectric layer, forming a second dielectric layer on the reagent layer, and reacting the reagent layer with one or more of the first dielectric layer and the second dielectric layer to transform the reagent layer into a self-forming barrier layer.

Further aspects include curing the second dielectric layer, with the reagent layer reacting with the second dielectric layer during the curing to form the self-forming barrier layer. Another aspect includes forming the reagent layer to a thickness of 2 to 500 Å.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 8 schematically illustrate a method for subtractive metal etching and barrier layer formation, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of damaged barrier layers leading to metal diffusing into dielectrics attendant upon removing barrier layers from the top of metal lines. In accordance with embodiments of the present disclosure, a self-forming barrier layer is formed without the need of RIE that otherwise would damage the barrier layer and liner layers.

Methodology in accordance with an embodiment of the present disclosure includes forming a metal line above a substrate, forming a reagent layer above the metal line and the substrate, and forming a dielectric layer on the reagent layer. During processing of the dielectric layer on the reagent layer, the reagent layer is transformed into a self-forming barrier layer.

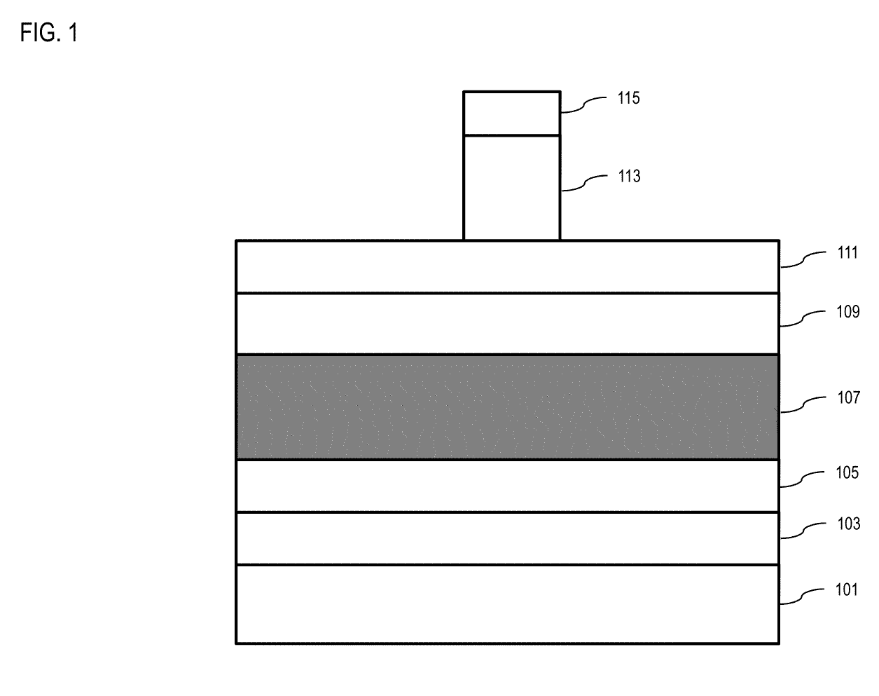

Adverting to FIG. 1, a method for forming a self-forming barrier layer, according to an exemplary embodiment, begins with a substrate 101. The substrate 101 may be any type of substrate for forming a semiconductor device, such as a Si substrate. Above the substrate 101, a bottom dielectric layer 103, a liner 105, a metal layer 107, and a hardmask 109 are sequentially formed. The bottom dielectric layer 103 may be formed of one or more dielectrics, such as silicon dioxide (SiO₂). The liner 105 may be formed of tantalum (Ta), and the metal layer 107 may be formed of any metal, particularly an electrically conductive metal, such as Cu. The hardmask 109 may be formed of any material that acts as a hardmask within the layers described and illustrated in FIG. 1, such as Ta. Above the hardmask 109 is another dielectric layer 111 that may be formed of one or more dielectrics, such as SiO₂. Above the dielectric layer 111 are a patterned optical planarizing (OPL) layer 113 and a resist layer 115, such as hydrogen silsesquioxane.

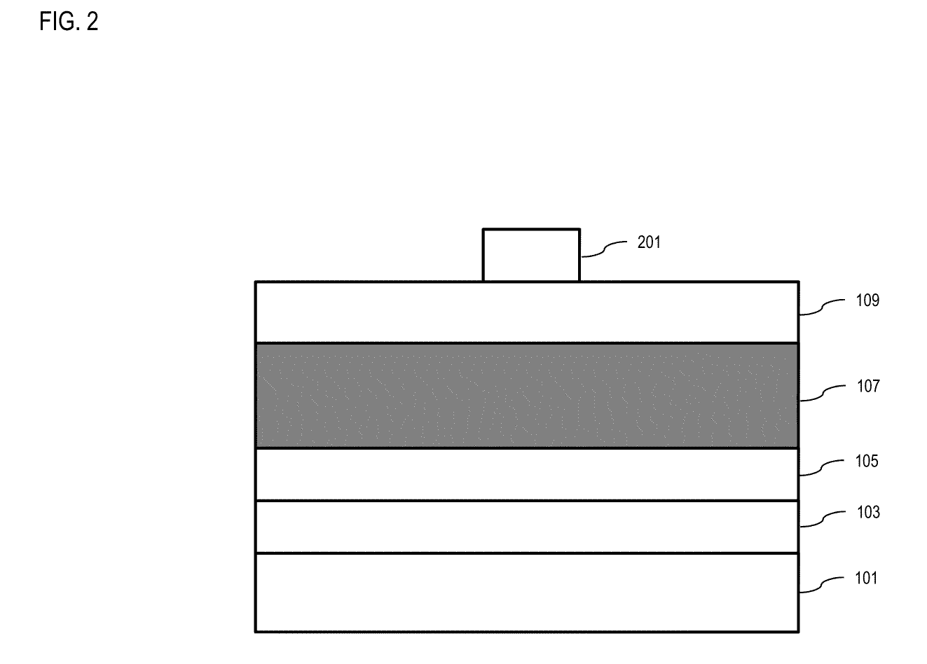

Adverting to FIG. 2, the dielectric layer 111 is patterned to form a patterned dielectric layer 201 using the OPL layer 113 and the resist layer 115 as a mask. Unwanted portions of the dielectric layer 111 may be removed according to any conventional processing. The OPL layer 113 and the resist layer 115 are subsequently removed.

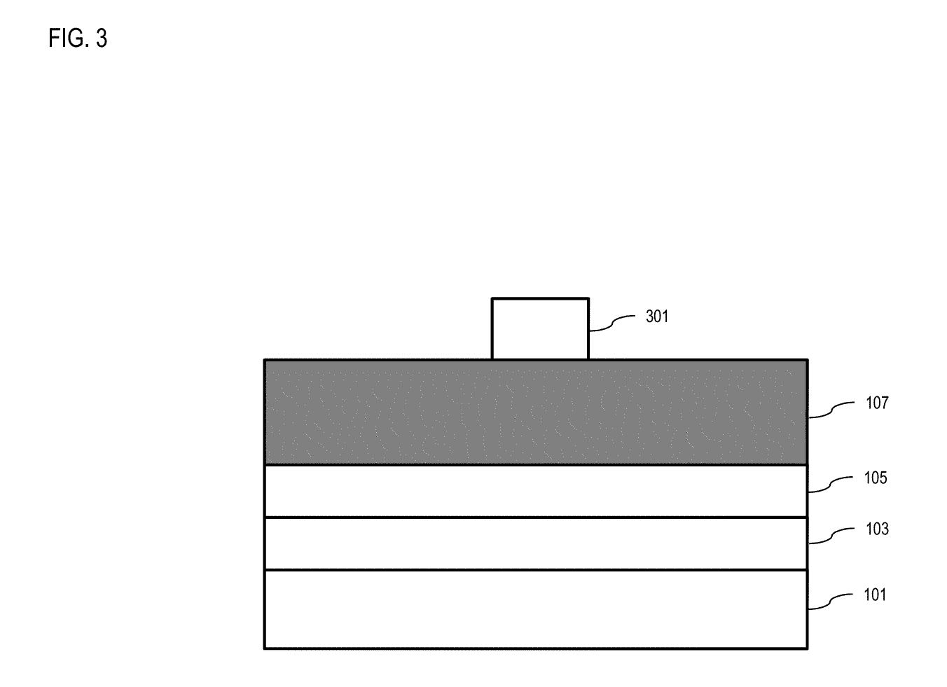

Next, the hardmask 109 is patterned according to the same pattern as the patterned dielectric layer 201 to form the patterned hardmask 301, as illustrated in FIG. 3. The hardmask 109 may be patterned according to any conventional processing. After forming the patterned hardmask 301, the patterned dielectric layer 201 is removed.

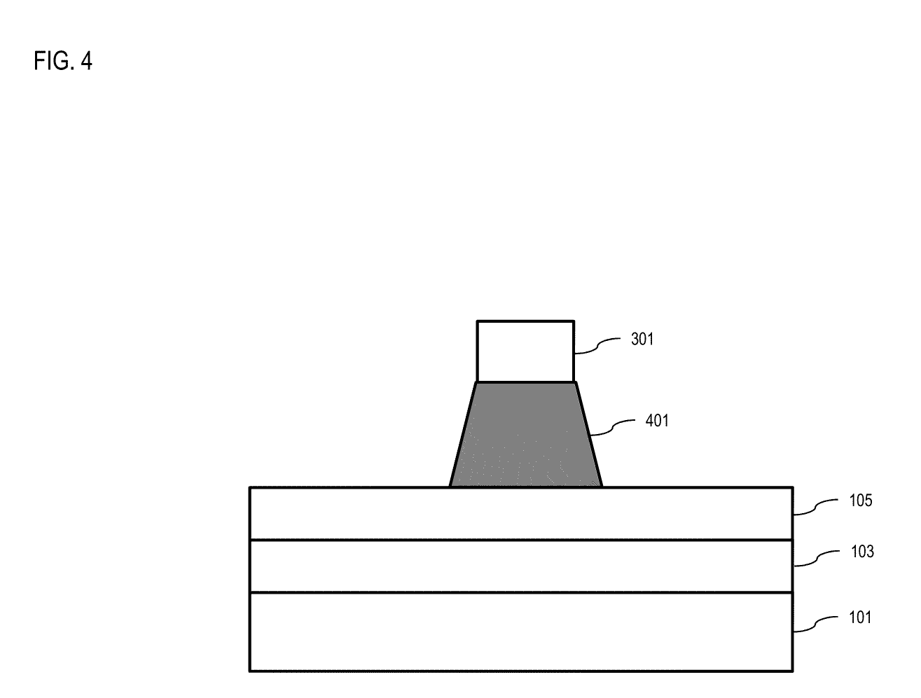

Adverting to FIG. 4, using the patterned hardmask 301, the metal layer 107 is patterned to form a patterned metal layer or metal lines 401. The metal layer 107 may patterned according to any conventional processing, such as by a methanol plasma etch. As illustrated, etching the metal layer 107 may generate a narrow top and a wide bottom of the metal lines 401.

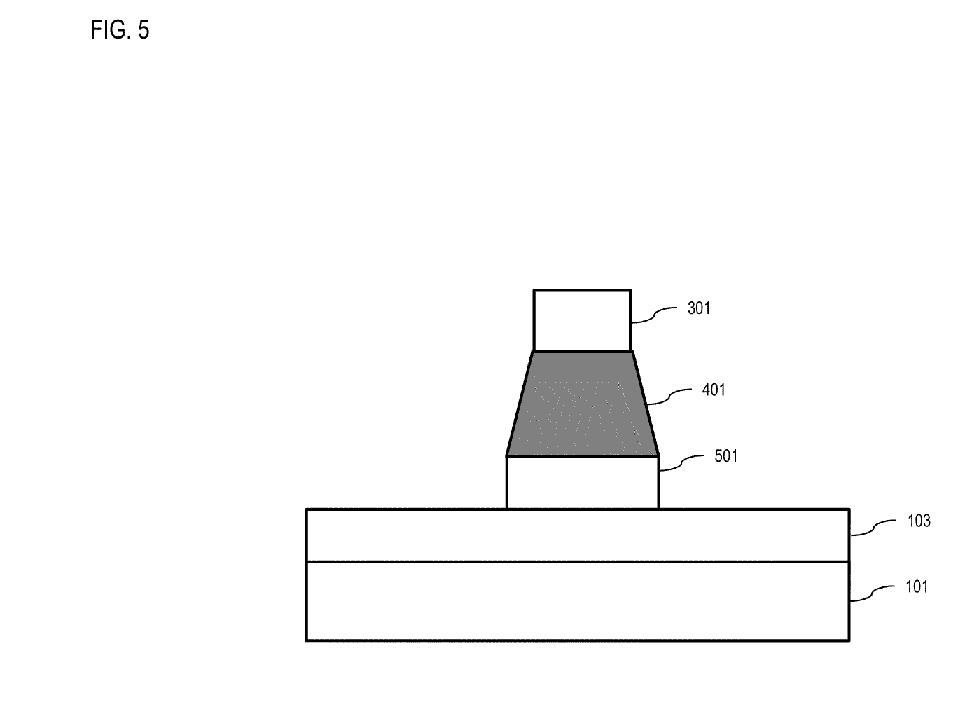

Next, using the metal lines 401 as a mask, the liner 105 is removed except from under the metal lines 401 to form a patterned liner 501, as illustrated in FIG. 5. The portions of the liner 105 to be discarded may be removed according to any conventional processing. In FIGS. 1 through 5, the layers illustrated within the figures and the process steps used to create the layers are merely exemplary. Other process steps and materials may be used to create the structure illustrated in FIG. 5.

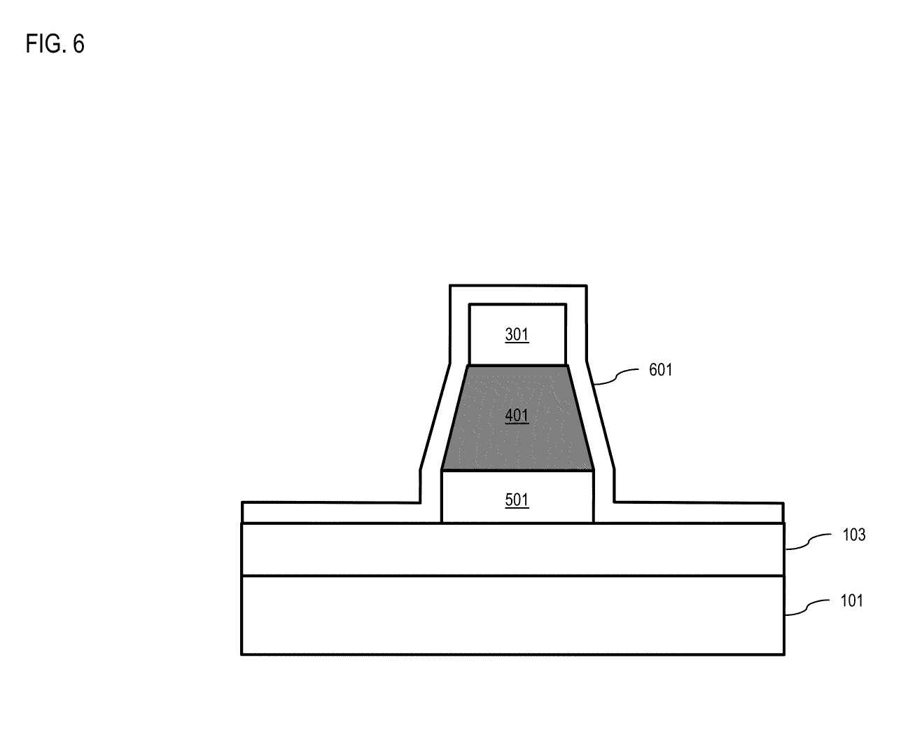

A reagent layer 601 is then conformally formed over the bottom dielectric layer 103 and the structure including the patterned hardmask 301, the metal lines 401, and the patterned liner 501, as illustrated in FIG. 6. The reagent layer 601 may be formed to a thickness of 2 to 500 Å and may be formed of Mn. Alternatively, the reagent layer 601 may be formed of Al, which also forms a self-forming barrier layer as discussed below. The reagent layer 601 may be formed according to various techniques, such as chemical vapor deposition (CVD) or ALD.

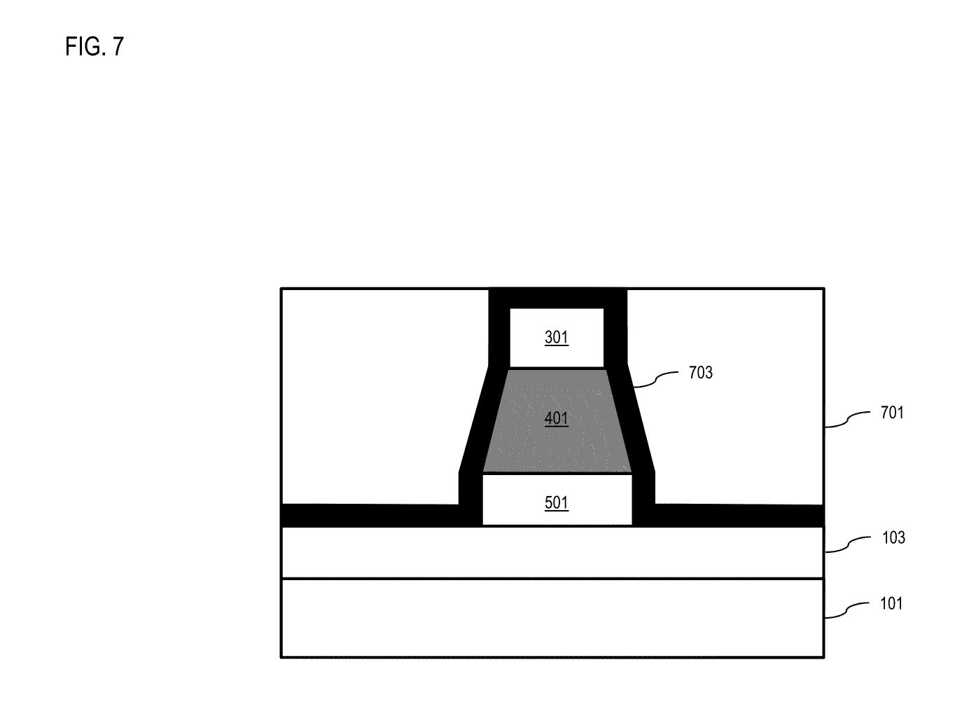

Adverting to FIG. 7, an upper dielectric layer 701 is formed over the reagent layer 601. The upper dielectric layer 701 may be formed of one or more silicon and oxide containing dielectrics such as ultralow-k dielectrics and SiO₂. During formation of the upper dielectric layer 701, such as by deposition of SiO₂, the conditions of the deposition and subsequent curing cause the silicon and oxygen in the upper dielectric layer 701 to combine with the material of the reagent layer 601, such as Mn, to transform the reagent layer 601 into a self-forming barrier layer 703. For example, a deposition temperature of 100° to 600° C. causes the silicon and oxygen to diffuse and combine with the Mn in the reagent layer 601, causing the transformation of the reagent layer 601 into the self-forming barrier layer 703. The reagent layer 601 may also combine with silicon and oxygen from the bottom dielectric layer 103 to transform the reagent layer 601 into the self-forming barrier layer 703. Thus, the self-forming barrier layer 703 may be formed of MnSiOₓ when the reagent layer 601 is formed of Mn.

Accordingly, a multi-step process of depositing a barrier layer of TaN and then removing portions of the TaN barrier layer by RIE can be replaced with a single step of depositing the reagent layer of Mn. Because the self-forming barrier layer 703 is non-conductive, it is not necessary to remove the self-forming barrier layer 703 surrounding the metal lines 401 between the upper dielectric layer 701 and the bottom dielectric layer 103. Subsequent high temperature processing steps, such as curing, that would otherwise already occur then transform the reagent layer into the self-forming barrier layer, without the requirement of additional processing, particularly RIE that damages the structure. Skipping the RIE improves the process margin because there is no RIE attack on the sidewalls of metal lines and liner above the metal lines.

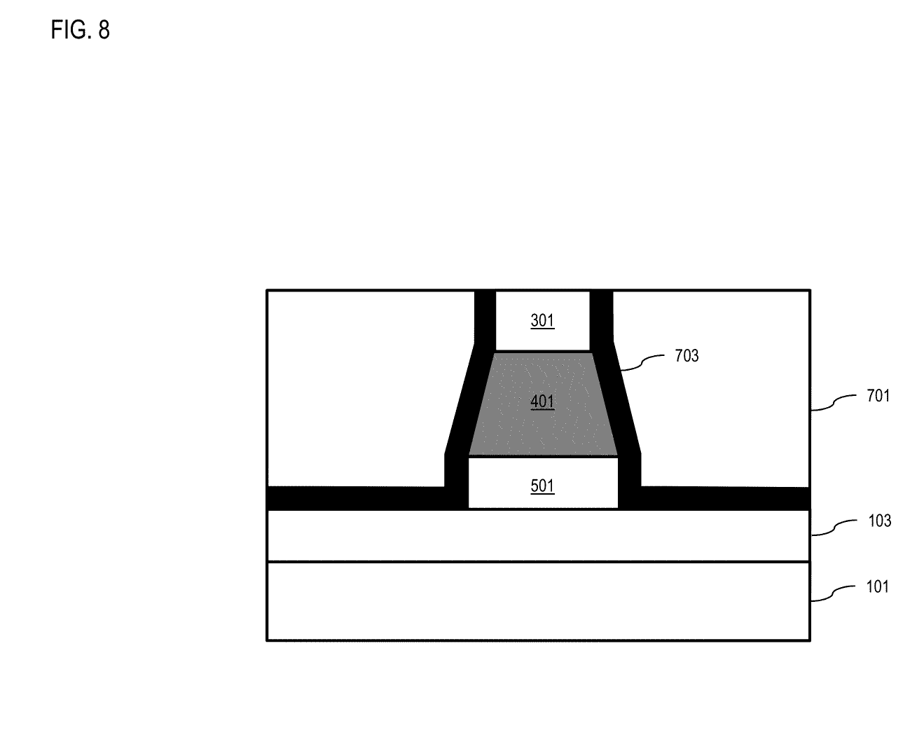

The self-forming barrier layer 703 and the upper dielectric layer 701 above the patterned hardmask 301 are then removed down to the patterned hardmask 301, such as by chemical mechanical polishing (CMP), as illustrated in FIG. 8.

The embodiments of the present disclosure achieve several technical effects, including improved process margin over conventional subtractive etching with RIE and a solution to time-dependent dielectric breakdown by avoiding the negative effects caused by the RIE, such as direct exposure of dielectrics to the metal lines allowing diffusion of metal into the dielectrics. Several technical effects also include better control of critical dimensions, as well as smaller critical dimensions at the top of the metal lines and larger at the bottom of the metal lines. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a metal line by patterning a conductive metal layer above the substrate by subtractive etching, wherein a top of the metal line is narrower in width than a bottom of the metal line as viewed in cross section;
forming a reagent layer of manganese (Mn) above the metal line and the substrate;
forming a dielectric layer of a material comprising silicon (Si) and oxygen (O) on the reagent layer; and
reacting the dielectric layer with the reagent layer to transform the reagent layer into the self-forming barrier layer,
wherein the self-forming barrier layer is formed of MnSiOₓ.

2. (canceled)

3. (canceled)

4. The method according to claim 1, comprising:
curing the dielectric layer at 100° to 600° C. to react the dielectric layer with the reagent layer.

5. The method according to claim 1, further comprising:
forming a second dielectric layer on the substrate prior to forming the metal line; and
forming the reagent layer on the second dielectric layer.

6. The method according to claim 5, further comprising:
reacting the second dielectric layer with the reagent layer to transform the reagent layer into the self-forming barrier layer.

7. The method according to claim 1, comprising:
forming the reagent layer to a thickness of 2 to 500 Å.

8. (canceled)

9. The method according to claim 1, wherein the conductive metal layer is formed of copper (Cu).

10. An apparatus comprising:
a substrate;
a metal line above the substrate, wherein a top of the metal line is narrower in width than a bottom of the metal line as viewed in cross section;
a self-forming barrier layer over the substrate and the metal line;
a dielectric layer above the self-forming barrier layer;
a hardmask between the top of the metal line and the self-forming barrier layer, wherein:
the dielectric layer formed of a material comprising silicon (Si) and oxygen (O), and
the self-forming barrier layer formed of MnSiOₓ.

11. (canceled)

12. (cancelled)

13. The apparatus according to claim 10, comprising:
the dielectric layer being cured at 100° to 600° C. to form the self-forming barrier layer.

14. The apparatus according to claim 10, further comprising:
a second dielectric layer below the metal line and above the substrate.

15. (canceled)

16. The apparatus according to claim 10, wherein the self-forming barrier layer is formed to a thickness of 2 to 500 Å.

17. The apparatus according to claim 10, wherein the metal line is formed of copper (Cu).

18. A method comprising:
forming a first dielectric layer above a substrate;
forming a metal layer above the first dielectric layer;
patterning the metal layer by subtractive etching to form metal lines, wherein a top of each metal line is narrower in width than a bottom of each metal line as viewed in cross section;
conformally forming a reagent layer above the metal lines on the first dielectric layer;
forming a second dielectric layer on the reagent layer; and
reacting the reagent layer with one or more of the first dielectric layer and the second dielectric layer to transform the reagent layer into a self-forming barrier layer, wherein:
the second dielectric layer comprises silicon (Si) and oxygen (O), and
the self-forming barrier layer comprises MnSiOₓ.

19. The method according to claim 18, comprising:
curing the second dielectric layer,
wherein the reagent layer reacts with the second dielectric layer during the curing to form the self-forming barrier layer.

20. The method according to claim 18, comprising:
forming the reagent layer to a thickness of 2 to 500 Å.
